(19) United States
(12) Patent Application Publication
(10) Pub. No.: US 2007/0013404 A1
(43) Pub. Date: Jan. 18, 2007

(54) Apparatus, customer tray, and method for testing semiconductor packages

(75) Inventors: Seok-young Yoon, Chungcheongnam-do (KR); Heui-seog Kim, Chungcheongnam-do (KR); Seon-ju Oh, Chungcheongnam-do (KR); Hyeck-jin Jeong, Chungcheongnam-do (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/488,087

(22) Filed: Jul. 18, 2006

(30) Foreign Application Priority Data
Jul. 18, 2005 (KR) 10-2005-0064769

(51) Int. Cl. G01R 31/26

(52) U.S. Cl. 324/765

(57) ABSTRACT

Provided is electrical test equipment and method for testing semiconductor packages in an in-tray state. The equipment may include a loading site configured to receive a customer tray having a plurality of semiconductor packages therein, a test site configured to align the customer tray, and also configured to test all the plurality of semiconductor packages in the customer tray in-situ, a sorting site configured to sort the tested plurality of semiconductor packages in the customer tray, and an unloading site configured to unload the sorted plurality of semiconductor packages in the customer tray. A method of testing a plurality of semiconductor may include loading a plurality of semiconductor packages into a customer tray, connecting the plurality of semiconductor packages in the customer tray to a test board by pressing the plurality of semiconductor packages onto the test board, testing all the semiconductor packages in the customer tray in-situ, removing defective semiconductor packages from the customer tray, and unloading non-defective semiconductor packages from the customer tray.

### PRIORITY CLAIM

A claim of priority is made to Korean Patent Application No. 10-2005-0064769, filed on Jul. 18, 2005, in the Korean Intellectual Property Office, the disclosure of which is incorporated herein in its entirety by reference.

### BACKGROUND

1. Field

Example embodiments relate to an apparatus and method for electrically testing semiconductor packages. For example, example embodiments may relate to an apparatus, a customer tray, and method for conducting a parallel direct current (DC) test on semiconductor packages in-tray or in-situ prior to a burn-in test.

2. Description of the Related Art

Semiconductor packages, for example, memories devices, may go through quality control electrical and/or reliability tests. A burn-in test, which is a type of reliability test, may be used to initially screen defective semiconductor packages.

Generally, semiconductor packages with DC characteristic defects may be detected and removed after a pre-burn-in test. If not, defective semiconductor packages may potentially damage normal adjacent semiconductor packages during a burn-in board test.

FIG. 1 is a flowchart illustrating a conventional method of electrically testing semiconductor packages prior to a burn-in board test. FIG. 2 is a perspective view of a pick-and-place tool 10 used for the electrical test.

Referring to FIGS. 1 and 2, semiconductor packages may be prepared for testing (S10), the semiconductor packages may be placed on a customer tray and loaded onto electrical test equipment for a pre burn-in test (S20). The electrical test equipment may be a handler connected to a tester.

Electrical test equipment, for example, a handler, may include a pick-and-place tool 10. The pick-and-place tool 10 may further include multiple (for example, four) vacuum suction units 12 for picking up a semiconductor package from the customer tray and transferring the semiconductor packages to a buffer region (S30). The four vacuum suction units 12 may insert semiconductor packages into a plurality of sockets connected to a test board of a tester. A direct current (DC) test may be conducted on the semiconductor packages (S40).

The pick-and-place tool 10 of FIG. 2 may transfer the DC-tested semiconductor packages back to the buffer region for sorting defective and non-defective semiconductor packages (S50). Non-defective semiconductor packages may be transferred by the pick-and-place tool 10 to the customer tray (S60) and unloaded from the electrical test equipment (S70).

As described above, according to the conventional electrical test method, the semiconductor packages in the customer tray may be picked up by a pick-and-place tool in multiple units (for example, four) and inserted into sockets of a test board. Hence, it may take considerable amount time to conduct an electrical test on all the semiconductor packages.

### SUMMARY

Example embodiments may provide an apparatus for simultaneously conducting a direct current (DC) test on semiconductor packages in an in-tray state, by connecting the semiconductor packages to a plurality of sockets on a test board, thereby enhancing test efficiency.

In an example embodiment, electrical test equipment for testing semiconductor packages may include a loading site configured to receive a customer tray having a plurality of semiconductor packages therein, a test site configured to align the customer tray, and also configured to test all the plurality of semiconductor packages in the customer tray in-situ, a sorting site configured to sort the tested plurality of semiconductor packages in the customer tray, and an unloading site configured to unload the sorted plurality of semiconductor packages in the customer tray.

In another example embodiment, a customer tray used in electrical test equipment for testing semiconductor packages may be configured to hold a plurality of semiconductor packages, the body including a plurality of pockets having an opening therein, and the opening configured to hold one of the plurality of semiconductor packages during an in-tray or in-situ testing.

In another example embodiment, a method of testing semiconductor packages may include loading a plurality of semiconductor packages into a customer tray, connecting the plurality of semiconductor packages in the customer tray to a test board by pressing the plurality of semiconductor packages onto the test board, testing all the semiconductor packages in the customer tray in-situ, removing defective semiconductor packages from the customer tray, and unloading non-defective semiconductor packages from the customer tray.

### BRIEF DESCRIPTION OF THE DRAWINGS

Example embodiments may become more apparent by the description of the detail example embodiments thereof with reference to the attached drawings in which:

FIG. 1 is a flowchart illustrating a conventional method of electrically testing semiconductor packages prior to a burn-in test;

FIG. 2 is a perspective view of a conventional pick-and-place tool used for an electrical test;

FIG. 3 is a flowchart illustrating a method of electrically testing semiconductor packages prior to a burn-in test according to an example embodiment;

FIG. 4 is a schematic plan view of electrical test equipment according to an example embodiment;

FIG. 5 is a side view of electrical test equipment according to an example embodiment;

FIG. 6 is an enlarged sectional view of a test site illustrated in FIG. 5;

FIG. 7 is a plan view of a customer tray according to an example embodiment;

FIG. 8 is an enlarged sectional view of a portion VIII of the test site illustrated in FIG. 6;

FIG. 9 is an enlarged sectional view of a portion IX of the test site illustrated in FIG. 6; and

FIG. 10 is a sectional view of a presser which may press down on a semiconductor package according to an example embodiment.

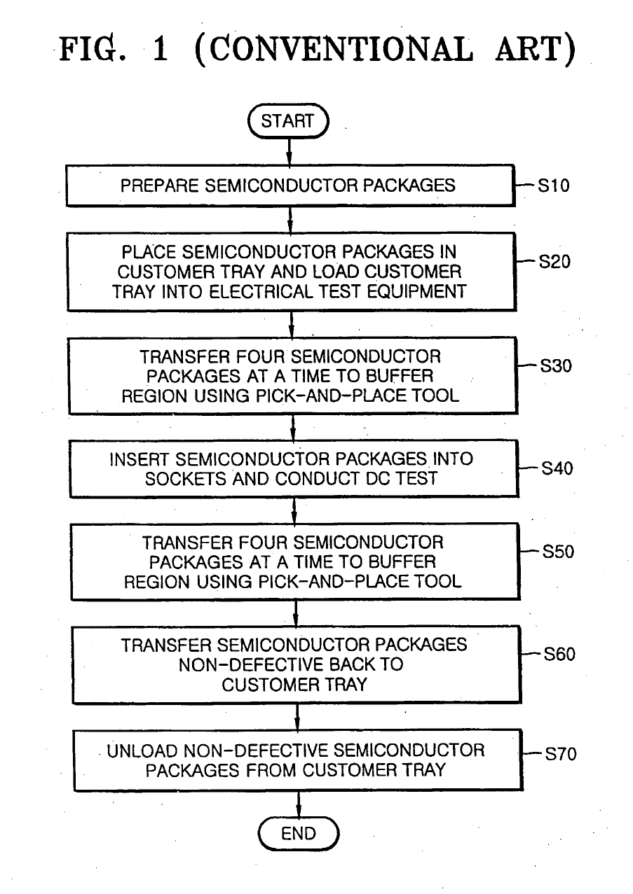

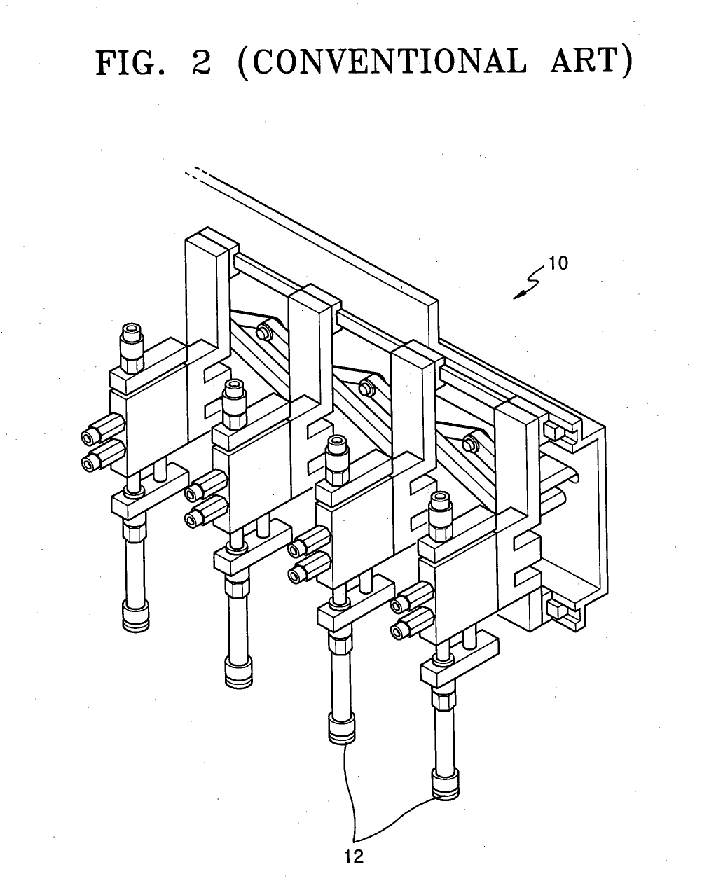

### DETAILED DESCRIPTION OF EXAMPLE EMBODIMENTS

Example embodiments will now be described more fully with reference to the accompanying drawings. Embodiments may, however, be embodied in many different forms and should not be construed as being limited to the example embodiments set forth therein; rather, these example embodiments are provided as working examples.

It will be understood that when an element or layer is referred to as being “on”, “connected to” or “coupled to” another element or layer, it may be directly on, connected or coupled to the other element or layer or intervening elements or layers may be present. In contrast, when an element is referred to as being “directly on,” “directly connected to” or “directly coupled to” another element or layer, there may be no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms may be only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a”, “an” and “the” may be intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the present invention are described herein with reference to cross-section illustrations that may be schematic illustrations of idealized embodiments (and intermediate structures) of the present invention. As such, variations from the shapes of the illustrations as a result, for example, of manufacturing techniques and/or tolerances, are to be expected. Thus, the example embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

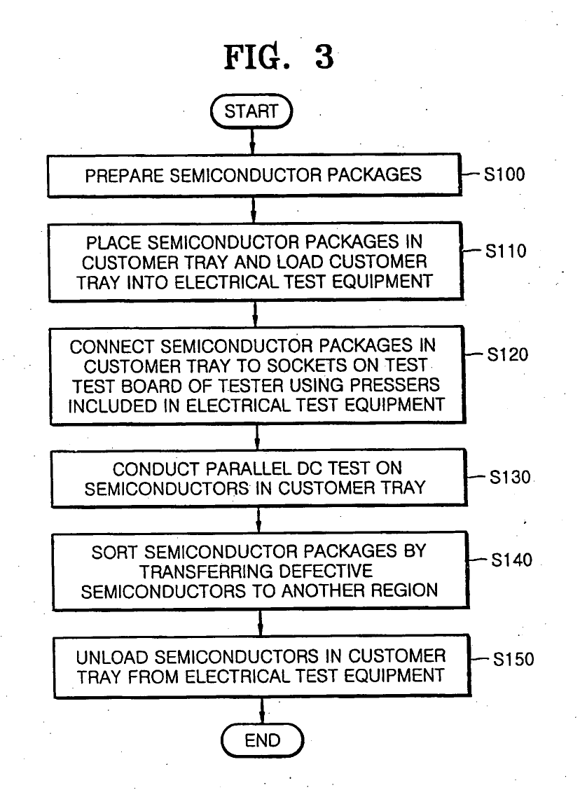

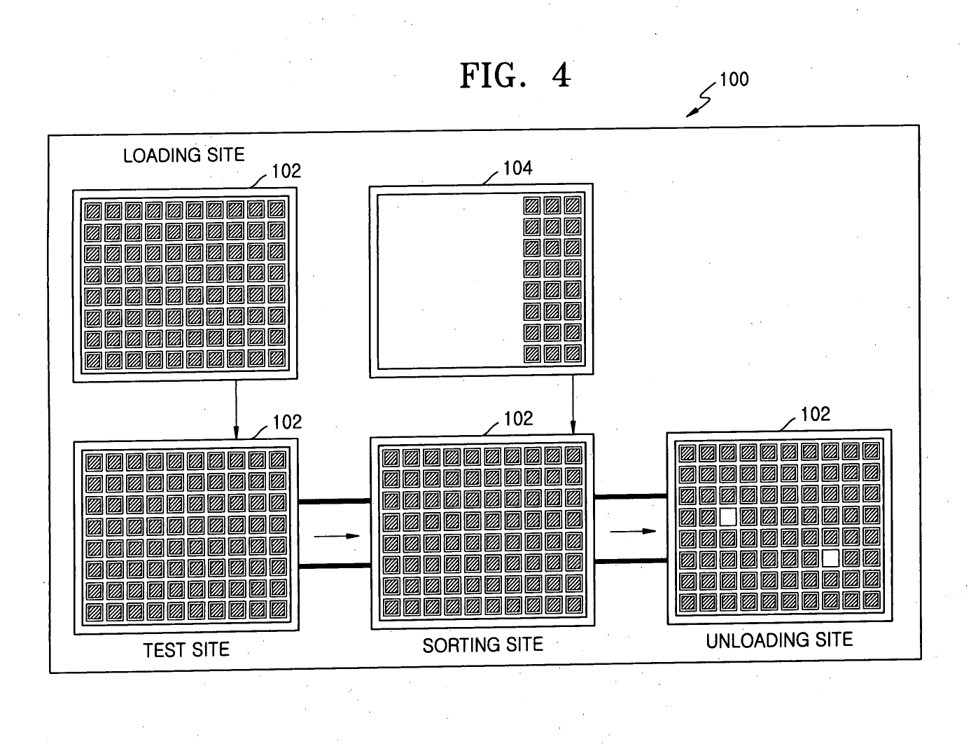

FIG. 3 is a flowchart illustrating a method of electrically testing semiconductor packages prior to a burn-in test according to an example embodiment. FIG. 4 is a schematic plan view of electrical test equipment according to an example embodiment.

Referring to FIGS. 3 and 4, semiconductor packages may be prepared for testing (S100), the semiconductor packages may be placed in a customer tray 102 and loaded onto electrical test equipment 100 for a pre burn-in test (S110). The electrical test equipment 100 may be a test handler connected to a tester. The electrical test equipment 100 may be a horizontal-type test handler in which semiconductor packages may be moved in a horizontal direction.

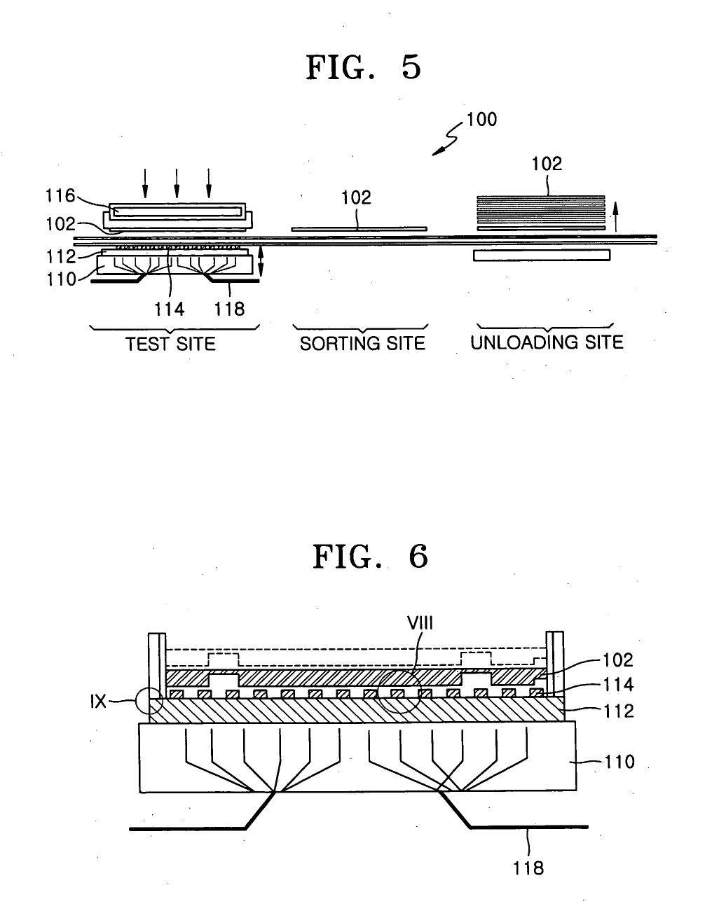

In electrical test equipment 100, the customer tray 102 may be introduced to a loading site, and transferred to a test site for connection with a tester. The semiconductor packages may be connected to a plurality of sockets 1 14 on a test board 112 of the tester using a presser 116(S120). See FIG. 5.

A parallel direct current (DC) test may be conducted on the semiconductor packages in the customer tray 102 (S130). While up to four semiconductor packages at a time may be electrically tested in the conventional electrical test method, all the semiconductor packages in the customer tray 102 may be electrically tested simultaneously in the electrical test method of an example embodiment. 8×10 or 12×16 semiconductor packages may be held in the customer tray 102 depending on the size of semiconductor packages.

When the parallel DC test is completed, the customer tray 102 may be transferred to a sorting site where the semiconductor packages in the customer tray 102 may be sorted into defective and non-defective semiconductor packages (S140). Defective semiconductor packages may be transferred to another customer tray 104. Semiconductor packages may be unloaded from the electrical test equipment 100 at an unloading site (S150).

FIG. 5 is a side view for illustrating electrical test equipment according to an example embodiment. Referring to FIG. 5, after a parallel DC test is conducted on semiconductor packages in a customer tray 102 in a test site, defective semiconductor packages may be removed at a sorting site, and non-defective semiconductor packages may be unloaded from the electrical test equipment 100 at an unloading site. In FIG. 5, reference numeral 110 may indicate a performance board of the tester, reference numeral 118 may indicate a signal line, reference numeral 112 may indicate the test board, reference numeral 114 may indicate the sockets on the test board 112, and reference numeral 116 may indicate the presser.

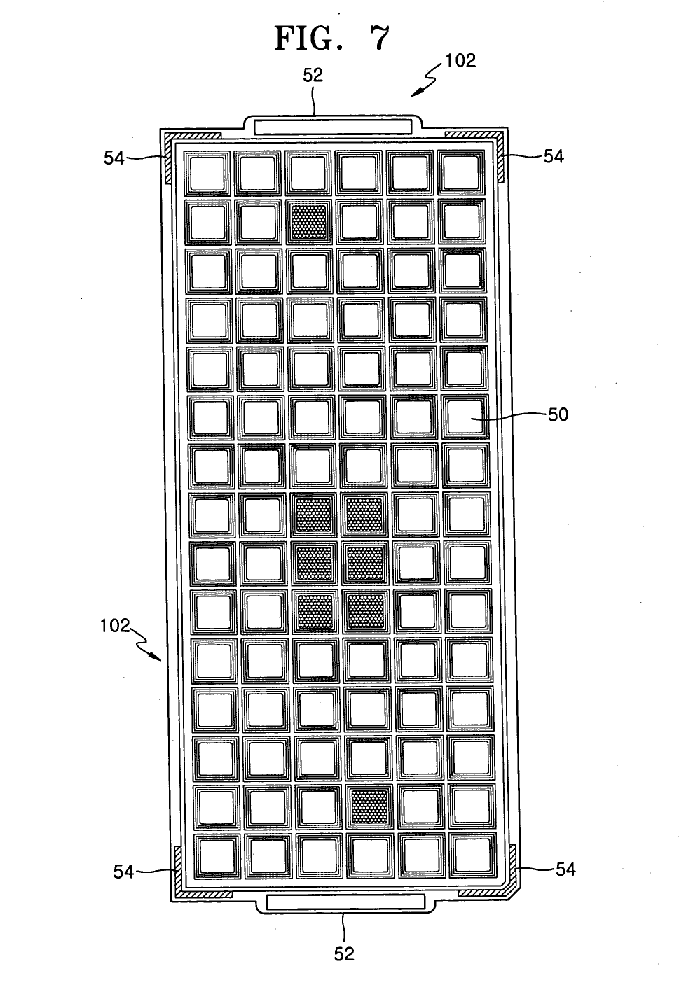

FIG. 6 is an enlarged sectional view of the test site illustrated in FIG. 5. FIG. 7 is a plan view of a customer tray according to an example embodiment.

Referring to FIGS. 6 and 7, a performance board 110 of a tester may be connected to a test site by a signal line 118. The test board 112 having sockets 114 thereon may be placed on and connected to the performance board 110. The sockets 114 may require arrangement on the test board 112 to correspond to the semiconductor packages arranged in the customer tray 102. Thus, when a presser 116, disposed above a customer tray 102, presses down on the semiconductor packages, solder balls 132, which may be external connection terminals of the semiconductor package, may be respectively connected to the socket 114 on the test board 112. Accordingly, the semiconductor packages may be electrically tested.

The customer tray 102 may include a plurality of pockets 50; each of the plurality of pockets 50 may hold a semiconductor package. Each semiconductor package may include solder balls 132 at a lower portion thereof. Openings (not shown) may be formed at a bottom surface of each of the pockets 50 such that the solder balls 132 of each semiconductor package may correspond and connect to the socket 114 on the test board 112. A pair of wing-shaped handles 52 may be formed at opposite ends of the customer tray 102 and may be used to transfer the customer tray 102. Slip locks 54 may be formed at each corners of the customer tray 102. Accordingly, when the customer trays 102 are stacked, semiconductor packages in the pockets 50 thereof may be protected.

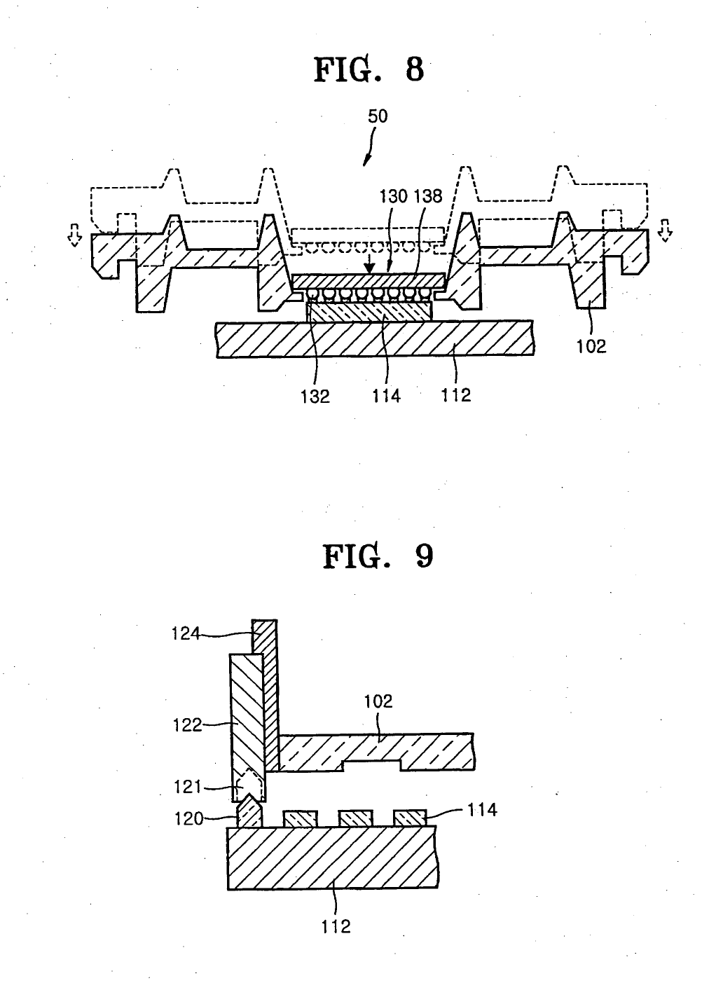

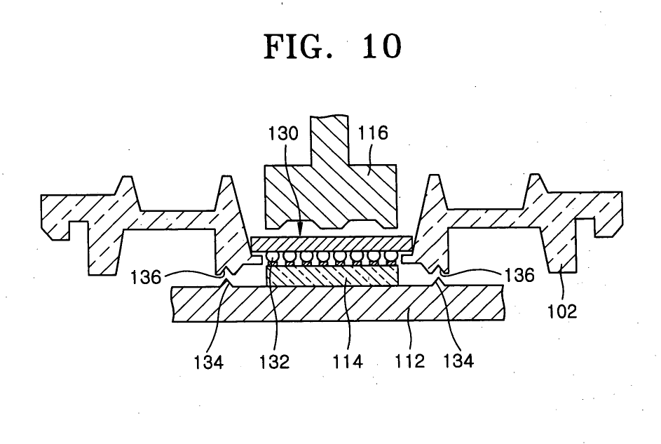

FIG. 8 is an enlarged sectional view of a portion VIII of the test site illustrated in FIG. 6. Referring to FIG. 8, for example, a ball grid array (BGA) semiconductor package may include solder balls 132 as external connection terminals. As described above, openings may be formed at a bottom surface of each of pockets 50 in a customer tray 102, and the solder balls 132 may be respectively connected to sockets 114 on a test board 112 through the openings. Therefore, a size of the openings formed in the bottom surface of each of the pockets 50 may be larger than the size of the solder balls 132. A presser 116 (see FIG. 5) which may press down on a body 138 of a semiconductor package 130 will be described in detail later with reference to FIG. 10.

FIG. 9 is an enlarged sectional view of a portion IX of the test site illustrated in FIG. 6. Referring to FIG. 9, a tray position alignment unit 120 may be formed at an edge of a test board 112. Generally, at least two tray position alignment units 120 may be used. When there are two tray position alignment units 120, they may be positioned diagonally opposite each other. The tray position alignment unit 120 may be coupled to a groove 121 formed at a bottom surface of a tray guide 122. The tray guide 122 may also be coupled to a rail post 124 such that the customer tray 102 may accurately align when it is coupled to sockets 114 on a test board 112.

It should be understood that there may be several tray alignment units 120, for example 4 or 8, and the customer tray 102 may be aligned in various ways.

FIG. 10 is a sectional view of a presser 116 which may press down on a semiconductor package according to an example embodiment. The presser 116 may press down on a body 130 of each semiconductor package 138 in the customer tray 102. The form and size of the presser 116 may vary as long as the presser 116 can press down on the body 130 of each semiconductor package 138 to connect the semiconductor packages 138 to sockets 114 on a test bard 112.

A plurality of pocket grooves 136 may be formed at bottom surfaces of pockets 50 of the customer tray 102. In addition, a plurality of pocket position alignment units 134 corresponding to the pocket grooves 136 may be formed on the test board 112. Therefore, the customer tray 102 may be aligned by the tray position alignment unit 120 of FIG. 9 on the edge of the test board 112 and further aligned by the pocket position alignment units 134 around the sockets 114 on the test board 112. Afterwards, a DC test may be conducted. At least two pocket position alignment units 134 and at least two pocket grooves 136 may be formed. When there are two pocket position alignment units 134 and two pocket grooves 136, they may be positioned diagonally opposite from each other.

As described above, according to example embodiments of the present invention, a parallel DC test may be conducted on semiconductor packages in an in-tray state. In other words, the semiconductor packages may be tested without being removed from a customer tray. Hence, the efficiency of a pre-burn-in test and productivity may be improved. Further, since semiconductor packages may be electrically tested while they are in the customer tray, the semiconductor packages may have reduced visual defects caused by physical damage during an electrical test.

While example embodiments have been particularly shown and described, it will be understood by those of ordinary skill in the art that various changes in form and details may be made therein without departing from scope of the present following claims.

What is claimed is:

1. Electrical test equipment for testing semiconductor packages, the equipment comprising:
a loading site configured to receive a customer tray having a plurality of semiconductor packages therein;
a test site configured to align the customer tray, and also configured to test all the plurality of semiconductor packages in the customer tray in-situ;
a sorting site configured to sort the tested plurality of semiconductor packages in the customer tray; and
an unloading site configured to unload the sorted plurality of semiconductor packages in the customer tray.

2. The equipment of claim 1, wherein the test site includes a test board having a plurality of sockets configured to correspond to the semiconductor packages arranged in the customer tray.

3. The equipment of claim 2, wherein the test board includes an alignment unit configured to align with the customer tray.

4. The equipment of claim 2, wherein the test site further includes a presser to press the plurality of semiconductor packages in the customer tray to connect with the corresponding plurality of sockets.

5. The equipment of claim 1, wherein the electrical test equipment is a horizontal-type test handler.

6. A customer tray used in electrical test equipment for testing semiconductor packages, comprising:
a body configured to hold a plurality of semiconductor packages, the body including a plurality of pockets having an opening therein, and the opening configured to hold one of the plurality of semiconductor packages during an in-situ testing.

7. The customer tray of claim 6, wherein the opening is configured to accommodate external connection terminals of one of the plurality of semiconductor packages, the external connection terminals being exposed at a bottom surface of the customer tray.

8. The customer tray of claim 6, wherein the customer tray includes at least two tray guides, each of the tray guide having a groove.

9. The customer tray of claim 8, wherein the at least two tray guides are formed in a diagonal direction from each other.

10. The customer tray of claim 8, wherein the tray guide is coupled to a rail post.

11. The customer tray of claim 8, further including at least one pair of wing shaped handles formed on opposite sides of the body.

12. The customer tray of claim 11, wherein the body includes at least four corners, and each of the four corners having a slip lock to protect the plurality of semiconductor packages.

13. A method of testing semiconductor packages, the method comprising:
loading a plurality of semiconductor packages into a customer tray;
connecting the plurality of semiconductor packages in the customer tray to a test board by pressing the plurality of semiconductor packages onto the test board;
testing all the semiconductor packages in the customer tray in-situ;
removing defective semiconductor packages from the customer tray; and
unloading non-defective semiconductor packages from the customer tray.

14. The method of claim 13, wherein the test is an electrical test performed prior to a burn-in test.

15. The method of claim 14, wherein the electrical test is a parallel test for testing direct current (DC) characteristics of the plurality of semiconductor packages.

16. The method of claim 13, wherein a hole is formed in a bottom surface of the customer tray where the plurality of semiconductor packages is loaded.

17. The method of claim 16, wherein a size of the hole in the bottom surface of the customer tray is a size capable of accommodating external connection terminals of the semiconductor package, so that the external connection terminals can be exposed from the bottom surface of the customer tray.

18. The method of claim 13, wherein the customer tray comprises a pocket position alignment unit which is formed in a bottom surface of each pocket of the customer tray and which aligns the customer tray with the sockets on the test board.

19. The method of claim 18, wherein the pocket position alignment unit is a pocket groove formed in the bottom surface of each pocket.

20. The method of claim 19, wherein at least two pocket grooves are formed.

21. The method of claim 21, wherein the at least two pocket grooves are formed in a diagonal direction.

22. The method of claim 13, wherein each semiconductor package includes solder balls as external connection terminals.

23. The method of claim 13, wherein the electrical test apparatus is a horizontal-type test handler.

24. The method of claim 13, wherein pressers of an electrical test apparatus press each body of the semiconductor packages in the customer tray.

25. The method of claim 24, wherein a number of pressers is the same as a number of the semiconductor packages in the customer tray.

26. The method of claim 13, wherein the test board comprises a tray position alignment unit on a surface of the test board for aligning a loading position of the customer tray.

27. The method of claim 26, wherein the test board further comprises a rail post coupled to the tray position alignment unit.

28. The method of claim 27, wherein the rail post comprises a tray fixing rail coupled to the rail post in a direction in which the customer tray is loaded.

29. The method of claim 13, wherein the electrical test is performed before a burn-in test.

30. The method of claim 29, wherein the electrical test is a parallel test for testing direct current characteristics of the semiconductor packages.
